(19) United States
(12) Patent Application Publication
(10) Pub. No.: US 2008/0164054 A1
(43) Pub. Date: Jul. 10, 2008

(54) PRINTED CIRCUIT BOARD CAPABLE OF VOID CONTROL DURING SURFACE MOUNTING PROCESS

(75) Inventors: Dong-Woo SHIN, Chungcheongnam-do (KR); Dong-Chun LEE, Chungcheongnam-do (KR); Seong-Chan HAN, Chungcheongnam-do (KR); Hyo-Jae BANG, Chungcheongnam-do (KR); Si-Suk KIM, Chungcheongnam-do (KR); Su-Jin JUNG, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 11/971,854

(22) Filed: Jan. 9, 2008

(30) Foreign Application Priority Data
Jan. 10, 2007 (KR) 2007-0003078

(51) Int. Cl. H05K 1/00; B23K 31/00

(52) U.S. Cl. 174/258; 228/203

(57) ABSTRACT

Example embodiments of the present invention include a printed circuit board (PCB) capable of controlling the size and position of voids during a surface mounting process. To this end, the PCB includes: an insulating plate made of an insulating material; printed circuit patterns formed on the insulating plate; a plurality of lands to support a plurality of solder joints, each land coupled to one end of each of the printed circuit patterns; and anti-wetting layers mounted on a surface of each of the lands for solder joint therein. The anti-wetting layers allow a void produced during a surface mounting process to move to a central surface on a pad, so that the solder joint reliability between the solder ball and the land is increased. As a result, the reliability of a semiconductor device is enhanced.

### CROSS-REFERENCE TO RELATED PATENT APPLICATION

This application claims the benefit of Korean Patent Application No. 10-2007-0003078, filed on Jan. 10, 2007, in the Korean Intellectual Property Office, the disclosure of which is incorporated herein in its entirety by reference.

### BACKGROUND OF THE INVENTION

1. Field of the Invention

The present invention relates to a printed circuit board having a semiconductor device mounted thereon, and more particularly, to a printed circuit board capable of void control on a land for solder joint when a semiconductor device having a solder ball or solder bump is mounted on the printed circuit board.

2. Description of the Related Art

Conventionally, a semiconductor package was mainly mounted on a printed circuit board (PCB) through leads. However, as the size of a semiconductor package is miniaturized, the semiconductor package is more commonly mounted on a surface of a PCB by using solder balls in place of leads. Accordingly, as the joint area of a semiconductor package and a PCB is scaled down, solder joint reliability (SJR) has appeared as an important factor in a surface mounting process.

The measurement for the SJR is accomplished through a reliability test such as a temperature cycle test. The temperature cycle test repeats a cycle in which the semiconductor package is first placed under a temperature condition of −25° C. for a certain time period and then placed under a temperature condition of 125° C. for a second time period. This test helps determine the functionality and integrity of a semiconductor package.

Using present techniques, a problem arises where the SJR between a solder ball and a PCB is lowered as a result of contraction and expansion of the solder ball because of differences in thermal expansion coefficients among a semiconductor chip, the PCB, and the solder ball.

FIG. 1 is a sectional view illustrating a problem which occurs as a result of attaching a ball grid array (BGA) package with solder balls on a printed circuit board (PCB).

FIG. 2 illustrates a plan view showing lands for solder joint formed on the PCB of FIG. 1.

Referring to FIGS. 1 and 2, the land 20 for solder joint of the PCB 18 may be subjected to electroless nickel immersion gold (ENIG) treatment on a surface of the land 20 such that a solder ball 12 is well fused on the land 20 for solder joint in a soldering process. In a surface mounting process where a semiconductor package 14 is mounted on the PCB 18, a soldering material such as flux or solder paste may be used to allow the solder ball 12 to be well attached on the land 20 for solder joint formed on the PCB 18. Meanwhile, gas is necessarily produced from such a soldering material through a chemical reaction of flux and solder paste in a reflow process.

The gas produced in the reflow process is produced in a porous form within the solder ball 12. The gas causes a defect of voids 24 by remaining within the solder ball 12 after the reflow process. The size of each of the voids 24 increases in proportion to the number of reflows in the surface mounting process. When the solder ball 12 is melted, the voids 24 move to an upper portion of the solder ball 12, and thus, migrate upward to an interface of a solder ball pad 10 as shown in FIG. 1. In general, the interface between the solder ball 12 and the solder ball pad 10 in the semiconductor package 14 comprises an area where stress is applied the most due to a difference of thermal expansion coefficients in a reliability test such as a temperature cycle test. In these figures, reference numeral 16 denotes a semiconductor chip, and reference numeral 22 denotes an insulating plate in the PCB 18.

Meanwhile, soldering materials have improved over time. Such materials as flux and solder paste have been made to reduce the occurrence of gas in a soldering process. However, because a soldering material producing little gas has a relatively low capability of removing a surface oxidation layer in a soldering process, there are downsides to such improvements.

FIG. 3 is a scanning electron microscope (SEM) photograph showing a section of a solder ball crack produced as a result of a void in the solder ball, after a BGA package is attached on a PCB. As shown in FIG. 3, a porous or more enlarged void appears in an upper portion of the solder ball. If a semiconductor package with such a structure is subjected to a reliability test, such as a temperature cycle test, cracks are produced at the joint interface between the solder ball land and the solder ball due to the porous or more enlarged void. Such a defect may be fatal to the reliability of a semiconductor package. The cracks may cause current to be leaked at a portion of the cracks. Even worse, the cracks may cause the connection of the solder ball to be partially or entirely cut. The prior art has achieved improved surface mounting processes by improving soldering materials, which in turn reduce the number of voids created during the soldering process. However, voids can still occur and the position and size of the voids are difficult to control. Accordingly, a need exists to effectively control the size and occurrence position of voids remaining within solder balls used in surface mounting processes.

### SUMMARY OF THE INVENTION

One example embodiment of the present invention includes a printed circuit board (PCB) structured to control voids during a surface mounting process, comprising: an insulating plate; printed circuit patterns formed on the insulating plate; a plurality of lands which are structured to support a plurality of solder joints, each land being coupled to at least one end of at least one of the printed circuit patterns; and an anti-wetting layer mounted on a surface of each of the lands.

Another example embodiment of the present invention includes a method for controlling voids in solder joints of a printed circuit board (PCB) during a surface mounting process, comprising: forming printed circuit patterns in an insulating plate; constructing a plurality of lands to support a plurality of solder joints, each land being coupled to at least one end of at least one of the printed circuit patterns; and depositing an anti-wetting layer on a surface of each of the lands.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view illustrating a problem which occurs as a result of attaching a ball grid array (BGA) package with solder balls on a printed circuit board (PCB);

FIG. 2 illustrates a plan view showing lands for solder joint formed on the PCB of FIG. 1;

FIG. 3 is a scanning electron microscope (SEM) photograph showing a section of a solder ball crack produced as a result of a void in the solder ball, after a BGA package is attached on a PCB;

FIG. 4 is a plan view showing anti-wetting layers respectively formed on lands for solder joint in a PCB according to an example embodiment of the present invention;

FIG. 5 is a SEM photograph showing a joint section of a solder ball using an anti-wetting layer according to an example embodiment of the present invention;

FIG. 6 is a sectional view of a PCB for a BGA package according to an example embodiment of the present invention;

FIG. 7 is a sectional view of a PCB for a multi-chip package according to an example embodiment of the present invention; and

FIG. 8 is a sectional view of a PCB for a semiconductor module according to an example embodiment of the present invention.

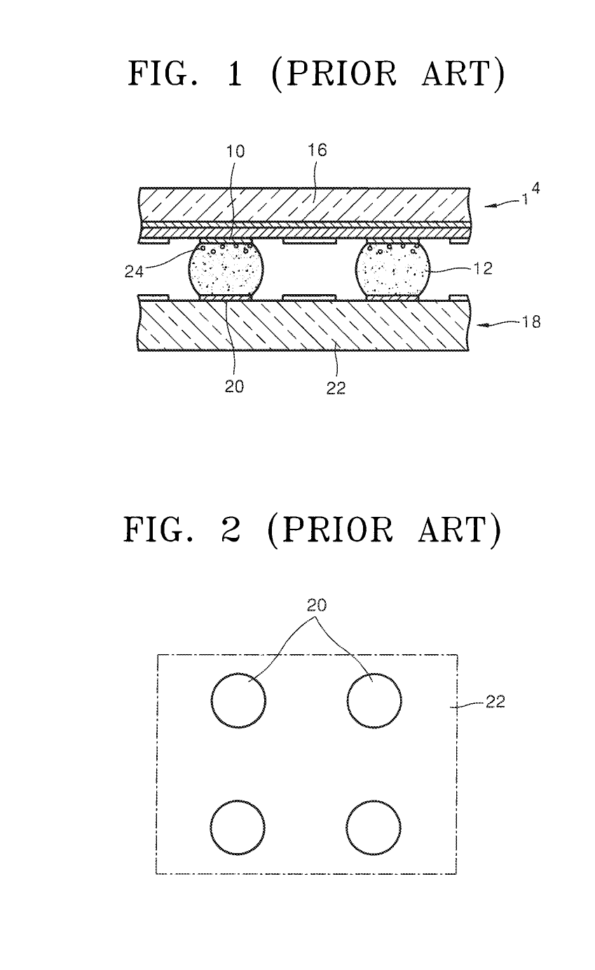

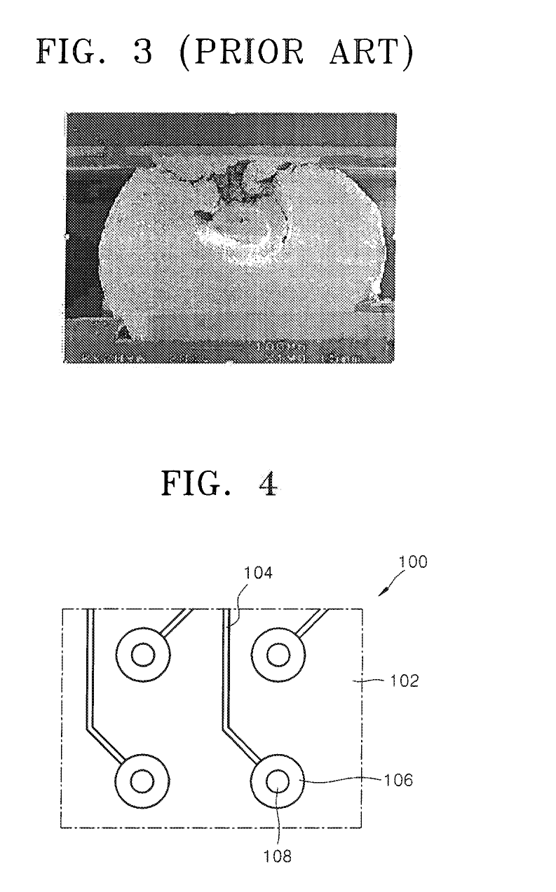

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art.

FIG. 4 is a plan view showing anti-wetting layers respectively formed on lands for solder joint in a PCB according to an example embodiment of the present invention. The PCB 100 includes elements capable of controlling voids according to an example embodiment of the present invention. These elements may include: an insulating plate 102 made of an insulating material, printed circuit patterns 104 formed on the insulating plate 102, lands 106 for solder joint, a printed circuit pattern 104 coupled to each of the lands 106, and anti-wetting layers 108 each mounted on a surface of each of the lands 106 for solder joint therein. Although not shown in this figure, the PCB 100 may also include a photo solder resister (PSR) opening only portions of the lands 106 for solder joint and covering substantially the entire area of the printed circuit patterns 104 and the insulating plate 102.

The insulating plate 102 may be a rigid PCB made of a phenol resin, epoxy resin, silicon resin, Teflon resin material, or a flexible PCB made of a polyimide resin material. Furthermore, some or all of the elements of PCB 100 may be applied to all single-face, double-face, and multi-layered PCBs.

Voids may be controlled using the anti-wetting layer 108. The anti-wetting layer 108 may be comprised of a PSR film or silk printing film on a central surface of the land 106 for solder joint. The anti-wetting layer 108 allows voids to be compulsorily formed on the land 106 for solder joint in a soldering process in which a semiconductor package is mounted on a PCB in a surface mounting process. A person with skill in the art will recognize that other materials capable of preventing the wetting of solder may be used in place of the anti-wetting layer 108.

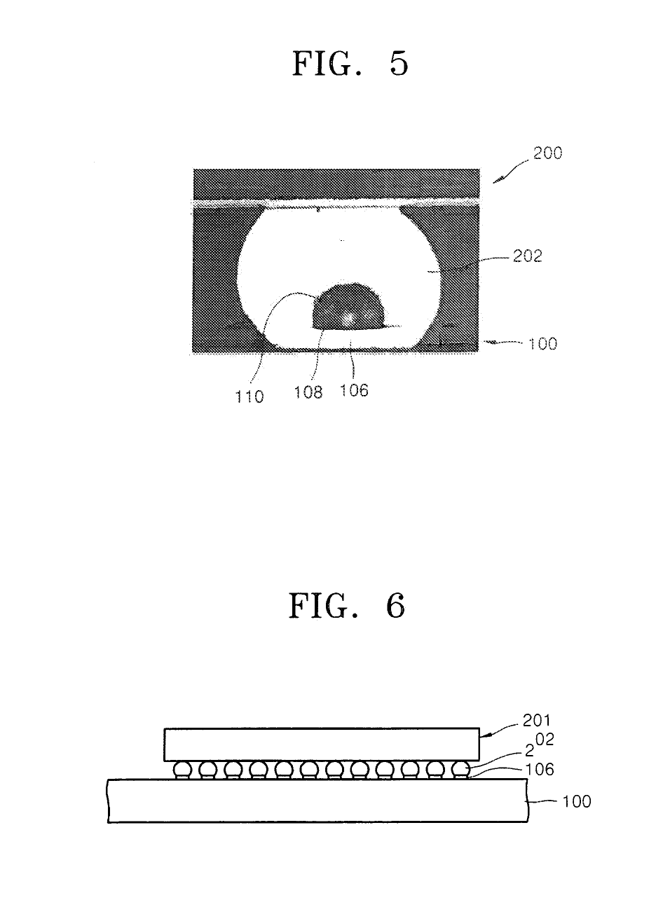

FIG. 5 is a scanning electron microscope (SEM) photograph showing a joint section of a solder ball using an anti-wetting layer according to an example embodiment of the present invention. When performing a surface mounting process in which a solder ball 202 of a semiconductor package 200 is connected to a PCB 100, the solder ball 202 comes into contact with a land 106, and the solder is spread to the surface while being melted. Such a phenomenon is referred to as wetting. To protect against wetting a particular location, an anti-wetting layer 108 is formed on a central surface of the land 106 using a PSR film or silk printing film. Thus, when wetting occurs in a soldering process, the fusion of solder is not accomplished on the anti-wetting layer 108, but space for a void 110 is provided on the anti-wetting layer 108. The space for a void 110 gathers gas produced from a soldering material such as flux or solder paste.

Although porous voids are formed, they are gathered on the anti-wetting layer 108 to form one large void 110. Further, although the number of reflows increases, the void 110 compulsorily formed on the anti-wetting layer 108 does not migrate upward; rather, the void 110 is fixed on the anti-wetting layer 108.

The void 110 with the aforementioned structure has a sufficiently high SJR as compared with conventional porous voids or voids moving to an upper portion of a solder ball. The reason is that the land 106, for solder joint of the PCB 100, experiences less stress than a solder ball pad formed in the semiconductor package 200. And the void 110 is compulsorily formed near to the land 106. Further, since the void 110 occurs at a central portion of the land 106, the void 110 has a structure capable of sufficiently tolerating stress in a horizontal direction, which is generated due to a difference of thermal expansion coefficients.

Therefore, in the PCB 100 with an anti-wetting layer according to example embodiments of the present invention, failure rarely occurs—even in a reliability test such as a temperature cycle test. As an example, when performing a temperature cycle test using 10 samples, failure was detected after 600 cycles in samples with no anti-wetting layer according to the prior art. However, failure was detected after 1000 cycles in samples each having an anti-wetting layer additionally formed on a surface of a land for solder joint.

FIG. 6 is a sectional view of a PCB for a BGA package according to an example embodiment of the present invention. The PCB 100 according to example embodiments of the present invention includes an insulating plate, printed circuit patterns, lands for solder joint and anti-wetting layers 106 each mounted on a surface of each of the lands for solder joint therein. The PCB 100 may be applied to not only a PCB for a mother board but also a PCB for a BGA package. A semiconductor device 201 is preferably mounted on the PCB 100 through solder bumps or solder balls 202 using a flip-chip connection method.

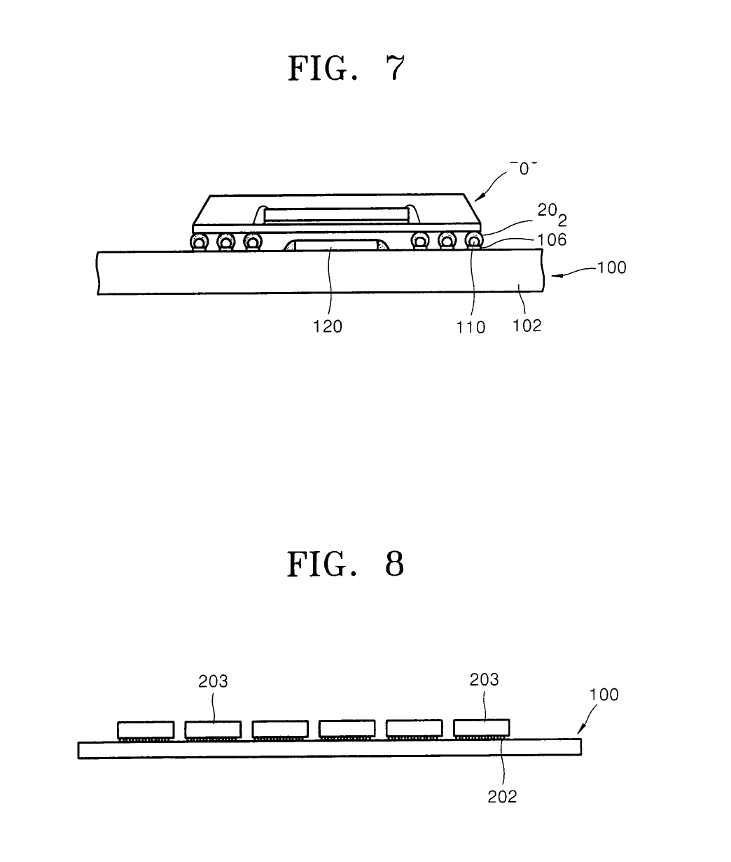

FIG. 7 is a sectional view of a PCB for a multi-chip package according to an example embodiment of the present invention. The PCB 100 capable of void control, according to an example embodiment of the present invention, may be applied to a PCB for a multi-chip package. Particularly, the size of a void 110 can be controlled by controlling the size of an anti-wetting layer 106. The size of the void 110 can also be controlled through an amount of gas produced from a soldering material, e.g., flux or solder paste. Accordingly, the size of a solder ball 202 can be controlled. Such a structure is more advantageous to a structure in which passive elements 120, such as resistors or capacitors, are vertically arranged below a semiconductor package 200 in a multi-chip package. That is, if the volume and height of the solder ball 202 are enlarged by controlling the size of the void 110, the passive elements 120 can be three-dimensionally arranged below the semiconductor package 200. For this reason, the entire size of the multi-chip package can be reduced.

FIG. 8 is a sectional view of a PCB for a semiconductor module according to an example embodiment of the present invention. The PCB 100 capable of void control, according to an example embodiment of the present invention may also be applied to a PCB for a board used in a DRAM semiconductor module. Since a large number of solder balls are generally attached to a semiconductor module, the entire semiconductor module will be defective if failure occurs even in one solder ball connection. To remedy such a disadvantage, the PCB 100, having anti-wetting layers according to example embodiments of the present invention, strengthens the joints of the solder ball as compared with the prior art; thus, defects caused by the failure of solder ball connections can be remarkably lowered.

According to the example embodiments of the present invention described above, an anti-wetting layer is separately mounted on a central surface of a land for solder joint in a PCB so that at least two particular advantages can be realized: first, a position of a void can be controlled and mounted only on an anti-wetting layer in a surface mounting process; second, since the size of a void can be controlled by controlling the size of an anti-wetting layer and an amount of gas produced from used soldering material, components can be three-dimensionally arranged.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A printed circuit board (PCB), comprising:
an insulating plate;
printed circuit patterns formed on the insulating plate;
a plurality of lands which are structured to support a plurality of solder joints, each land being coupled to at least one end of at least one of the printed circuit patterns; and
an anti-wetting layer mounted centrally on a surface of each of the lands to control a position and a size of a void within the associated solder joint,
wherein the anti-wetting layer is structured to prevent an upward migration of the void within the solder joint associated with each of the lands.

2. The PCB of claim 1, wherein the anti-wetting layer is structured to gather porous voids into a single large void, the single large void being structured to gather gas produced from soldering material used during a surface mounting process.

3. The PCB of claim 1, wherein the anti-wetting layer is one of a photo solder resistor (PSR) film and a silk printing film.

4. A printed circuit board (PCB), comprising:
an insulating plate;
printed circuit patterns formed on the insulating plate;
a plurality of lands which are structured to support a plurality of solder joints, each land being coupled to at least one end of at least one of the printed circuit patterns; and
an anti-wetting layer mounted on a surface of each of the lands.

5. The PCB of claim 4, wherein the anti-wetting layer mounted on the surface of each land is structured to control a position of a void within the solder joint associated with each land.

6. The PCB of claim 5, wherein the anti-wetting layer mounted on the surface of each land is structured to prevent an upward migration of the void within the solder joint associated with each land.

7. The PCB of claim 4, wherein the anti-wetting layer is structured to gather porous voids into a single large void, the single large void being structured to gather gas produced from soldering material used during a surface mounting process.

8. The PCB of claim 4, wherein a size of a void within the solder joint associated with each land is determined by controlling a size of the anti-wetting layer mounted on the surface of each land.

9. The PCB of claim 4, wherein the PCB is structured to support a ball grid array (BGA).

10. The PCB of claim 9, wherein the lands are structured to support the solder joints with a semiconductor device, the solder joints forming a coupling through at least one solder ball.

11. The PCB of claim 9, wherein the lands are structured to support the solder joints with a semiconductor device, the solder joints forming a coupling through at least one solder bump.

12. The PCB of claim 4, wherein the PCB is structured to support a multi-chip package (MCP).

13. The PCB of claim 4, wherein the PCB is structured to support a semiconductor memory module.

14. A method for controlling voids in solder joints on a printed circuit board (PCB) during a surface mounting process, comprising:
forming printed circuit patterns on an insulating plate;
constructing a plurality of lands to support a plurality of solder joints, each land being coupled to at least one end of at least one of the printed circuit patterns; and
depositing an anti-wetting layer on a surface of each of the lands.

15. The method of claim 14, wherein depositing the anti-wetting layer includes controlling a position of a void within the solder joint associated with each land.

16. The method of claim 15, wherein the anti-wetting layer deposited on the surface of each land prevents an upward migration of the void within the solder joint associated with each land.

17. The method of claim 14, wherein the anti-wetting layer gathers porous voids into a single large void to gather gas produced from soldering material used during the surface mounting process.

18. The method of claim 14, wherein a size of a void within the solder joint associated with each land is determined by controlling a size of the anti-wetting layer mounted on the surface of each land.

19. The method of claim 14, wherein the anti-wetting layer is one of a photo solder resister (PSR) film and a silk printing film.

20. The method of claim 14, wherein depositing the anti-wetting layer includes forming the anti-wetting layer at substantially the center of each land.
